(19) United States
(12) Patent Application Publication
(10) Pub. No.: US 2007/0158841 A1
(43) Pub. Date: Jul. 12, 2007

(54) Structure of Ball Grid Array package

(75) Inventor: Chi-Jang Lo, Taipei (TW)

Correspondence Address: BIRCH STEWART KOLASCH & BIRCH, PO BOX 747, FALLS CHURCH, VA, 22040-0747, US

(73) Assignee: Powertech Technology Inc.

(21) Appl. No.: 11/330,253

(22) Filed: Jan. 12, 2006

(51) Int. Cl. H01L 23/48

(52) U.S. Cl. 257/737; 257/738; 257/E23.069

(57) ABSTRACT

A structure of Ball Grid Array package (BGA) is provided. The plurality of bumps are attached on a substrate when processed the surface mount technology (SMT) may get stronger support, avoid the assembly structure disintegration when bearing an external force. When user uses a semi-conductor module, the assembly structure will not be damaged by external force.

### BACKGROUND OF THE INVENTION

1. Field of the Invention

The present invention relates to an assembly structure of semi conductor and more especially relates to a Ball Grid Array (BGA) package with the plurality of bumps as stand support.

2. Description of the Prior Art

The assembly structure of semi-conductor, a electric apparatus which carry active components, such as semi-conductor die. FIG. 1 is a cross-sectional diagram illustrating the structure of the prior assembly structure of semi-conductor as Ball Grid Array (BGA) package. Shown in FIG. 1, the structure mounting a die 110 on a surface of a substrate 100, processing wire bonding to forming the electric connection between the die 110 and the substrate 100. Then cover the die 100 and the wire 120 with a molding compound and mounting the plurality of conductive balls 140 by grid array method on the other surface of the substrate 100. The conductive ball 140 is the input/output (I/O) connector forming the electric connection between the die 110 inside of the package and the external apparatus, such as the Printed Circuit Board 150 (PCB). However when processing the surface mount technology (SMT) to mount the BGA package to the external apparatus the corner of the package is easily to disintegrate and the die inside of the package is easily to be damaged also when bears an external force 160. The method to improve the prior art is to fill a underfill into a gap between the assembly package and the PCB in order to enhance the supporting force of assembly package itself. However, the method of fill the underfill will increase the extra cost from the underfill; The PCB design need to re-layout to add extra ball area and extra conductive ball cost if attach the dummy ball on. These are urgent issues that enterprises need to overcome currently.

### SUMMARY OF THE INVENTION

According to the issue mentioned previously, the present invention provides a structure of Ball Grid Array (BGA) package with the plurality of bumps as stand support to improve the mentioned issue.

It is the purpose of this invention to provide the structure of Ball Grid Array package with the plurality of bumps on the corner of the substrate. Therefore, the assembly structure of semi-conductor has a supporting force and avoid disintegration when bears an external force during SMT process.

Another object of this invention is to provide the structure of Ball Grid Array (BGA) package with the extra bumps the structure can avoid damage when bears an external force (such as user exert too much strength on package) when user using the semi-conductor module.

Another object of this invention is to provide the structure of Ball Grid Array (BGA) package by utilizing the molding compound forming the plurality of bumps when assemble the die. No extra cost needed. It can reduce the production cost.

Accordingly, one embodiment of the present invention provides a structure of Ball Grid Array (BGA) package. It contains a substrate that has an upper surface and a lower surface. The lower surface has pluralities of electric terminals, the upper surface of substrate has the die on it and the die electrically connected with pluralities of electric terminals. And the plurality of through holes penetrating through the substrate and locates around the die symmetrically. Furthermore cover the die fill the plurality of through holes with the molding compound and forming the plurality of bumps on the lower surface of the substrate. Locating the plurality of conductive balls to electric terminals individually.

These and other objects will appear more fully from the specification below.

### BRIEF DESCRIPTION OF THE DRAWINGS

FIG. 1 is a cross-sectional diagram illustrating the prior art of structure of Ball Grid Array (BGA) package;

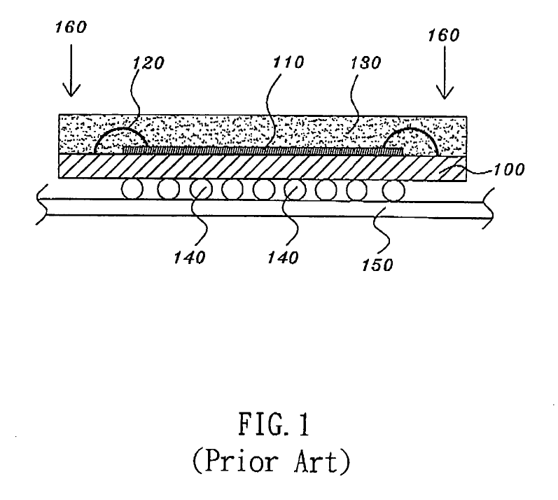

FIG. 2A is a cross-sectional diagram illustrating a structure of Ball Grid Array package in accordance with an embodiment of the present invention;

FIG. 2B is a bottom view diagram of FIG. 2A;

FIG. 2C is a cross-sectional diagram illustrating a die mount on a substrate in accordance with an embodiment of the present invention;

FlG. 2D is a cross-sectional diagram illustrating the substrate and the die model during the molding process in accordance with an embodiment of the present invention;

FIG. 3 is a cross-sectional diagram illustrating an electric apparatus structure in accordance with another embodiment of the present invention; and

FIG. 4A, FIG. 4B, FIG. 4C and FIG. 4D are illustrations of a bottom view of the structure of BGA package in accordance with different embodiments of the present invention.

### DETAILED DESCRIPTION OF THE INVENTION

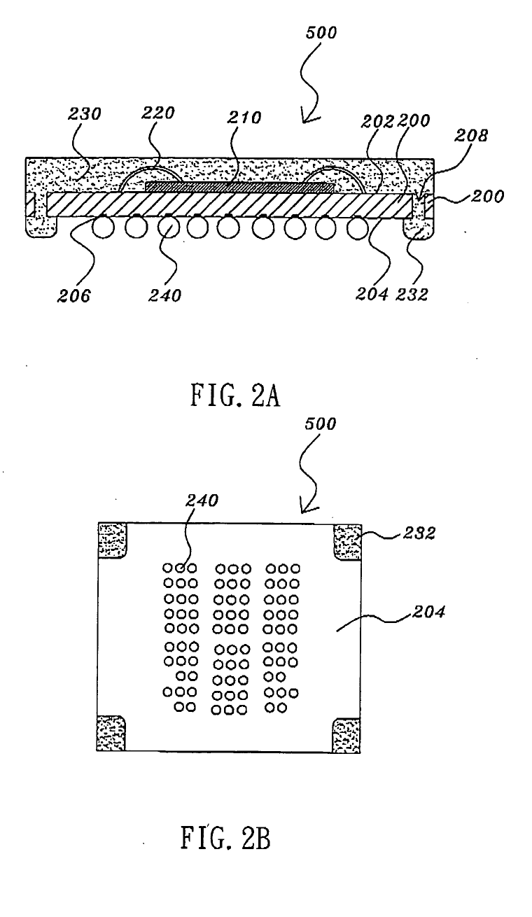

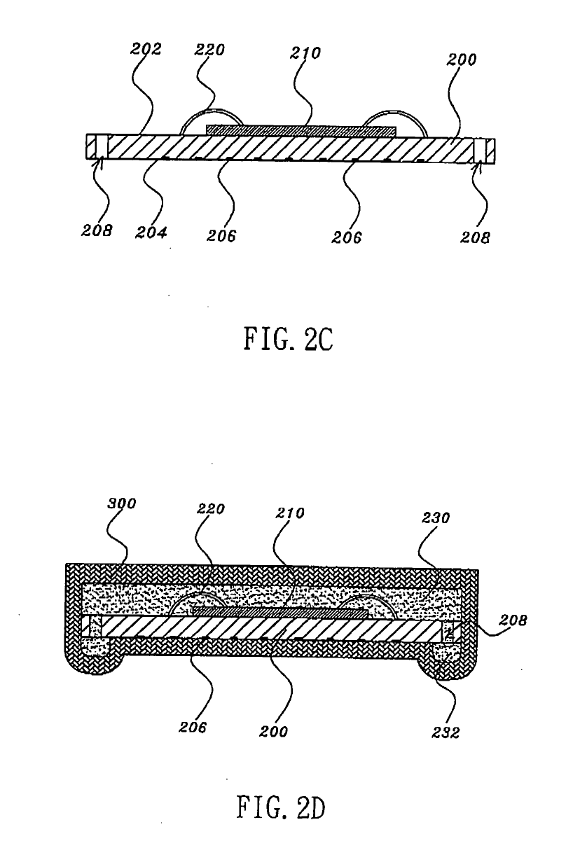

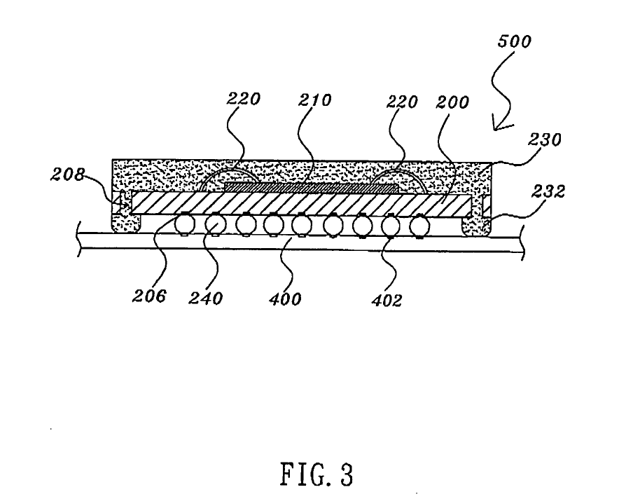

To explain a structure of Ball Grid Array(BGA) package with a preferred embodiment of the present invention, FIG. 2A is a cross-sectional diagram illustrating a structure of Ball Grid Array(BGA) package in accordance with an embodiment of the present invention. FIG. 2B is a bottom view diagram of the embodiment of the present invention. Shown in FIG. 2A and 2B, in this embodiment a Ball Grid Array(BGA) package 500 includes a substrate 200 that is made of polyimide, glass, aluminum oxide, beryllium oxide or elastomer. The substrate 200 includes an upper surface 202 and a lower surface 204. There are a plurality of electric terminals 206 positioned on the lower surface 204 which are electrically connected a die 210 upon the upper surface 202. In one embodiment, electric connection be accomplished by wire bonding the pluralities of wires 220 made of aurum material (Au). Besides, the plurality of through holes are penetrated through the substrate 200 and located around the corner with weak supporting force of the die 210 symmetrically. Then a molding compound 230 made of epoxy covers the die 210 and the plurality of wires 220 and fill into the plurality of through holes 208 to form pluralities of bumps 232 which protrude from the lower surface 204 of the substrate 200. The bumps 232 enhance the supporting force of whole structure of BGA package 500 and avoid the internal die be damaged or disintegration caused by external force. Next, the plurality of conductive balls 240 made of metal tin (Sn) is mounted on the plurality of electric terminals 206 of the lower surface 204 of the substrate 200. The plurality of electric terminals 206 may be the input/output connectors to connect with an external apparatus as a interface connection, such as PCB. The plurality of bumps 232 formed by the molding compound 230 may enhance the supporting force of BGA package 500 but not limited on the BGA package 500 on this embodiment of the present invention. It can be suitable for all package of assembly structures to use the plurality of conductive balls 240 accomplish electric connection, for example, Fine Pitch Ball Grid Array (FBGA), Very Fine Pitch Ball Grid Array (VFBGA), Micro Ball Grid Array (PBGA) or Window Ball Grid Array (WBGA) and etc. Comparatively referring FIG. 2B is a bottom view diagram of an embodiment of the present invention. In this embodiment, the plurality of bumps 232 is located at the four relative corners of the substrate 200. The four corners of the substrate 200 are the weakness places of the assembly package and easy to disintegrate by external force. The plurality of bumps 232 provides a better supporting force by being located on the corner of the substrate 200. But this is the only one embodiment of the present invention, the shape of the bump 232, the location and the amount of the bump 232 are not limited as shown in this embodiment.

In one embodiment, please refer FIG. 2C and FIG. 2D. The FIG. 2C and FIG. 2D are the cross-sectional diagrams illustrating the die mount on the substrate, the substrate and the die model during the molding process in accordance with an embodiment of the present invention individually. Shown in FIG. 2C and FIG. 2D, the die 210 is attached to the upper surface 202 of the substrate 200 first and electrically connected the substrate 200. Then the substrate 200 and the die 210 are put into a cavity 300 and processed the grouting process. The molding compound 230 made of epoxy is filled into the cavity 300 and covered the die 210, the substrate 200, and the wire 220. The electric terminals 206 of the lower surface 204 on the substrate 200 will not be covered and each through hole 208 was filled with the molding compound 230 in the cavity 300. Next, a curing process is implemented to make the molding compound harden and take it out of the cavity after hardening. At the mean time, the molding compound 230 in the through hole 208 is formed as the bumps 232. Eventually, the plurality of conductive balls 240 (shown in FIG. 2A) for example metal tin (Sn) are mounted to electric terminal 206s by electric connection separately. Therefore, the semi-conductor assembly process may be completed.

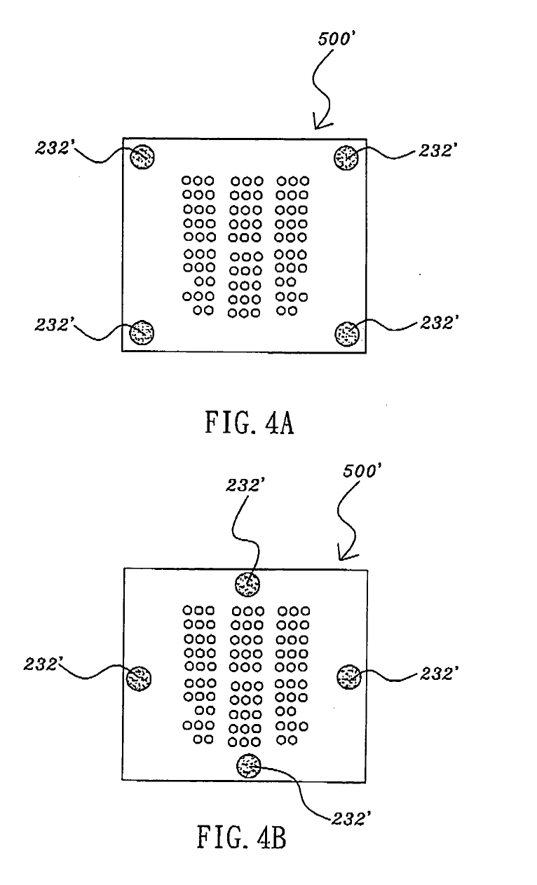

Furthermore, FIG. 3 is a cross-sectional diagram illustrating an electric apparatus structure in accordance with another embodiment of the present invention. It includes a BGA package 500 and a PCB 400 of the previous embodiment. The PCB 400 has a conductive connection region 402 that may be configured for electrically connecting with the conductive balls 240 on the substrate 200. The substrate 200 is made of polyimide, glass, aluminum oxide, beryllium oxide or elastomer. When the BGA package 500 mounted on the PCB 400 and formed the electric connection with the PCB 400 of an embodiment, the height of the bumps 232 of the BGA package 500 (which are made of grout the molding compound) shorter than the height of the gap between the BGA package 500 and the PCB 400. As this result, the bumps 232 may just be attached to the PCB 400 to provide a supporting force when bears an external force to avoid BGA package 500 disintegration or damage due to oppress by an external force. In one embodiment, the shape of the bumps 232 may be rectangle prism, triangular prism, sphere, elliptic cylinder, or polygon prism, bar prism or polyhedron to provide more forceful supporting.

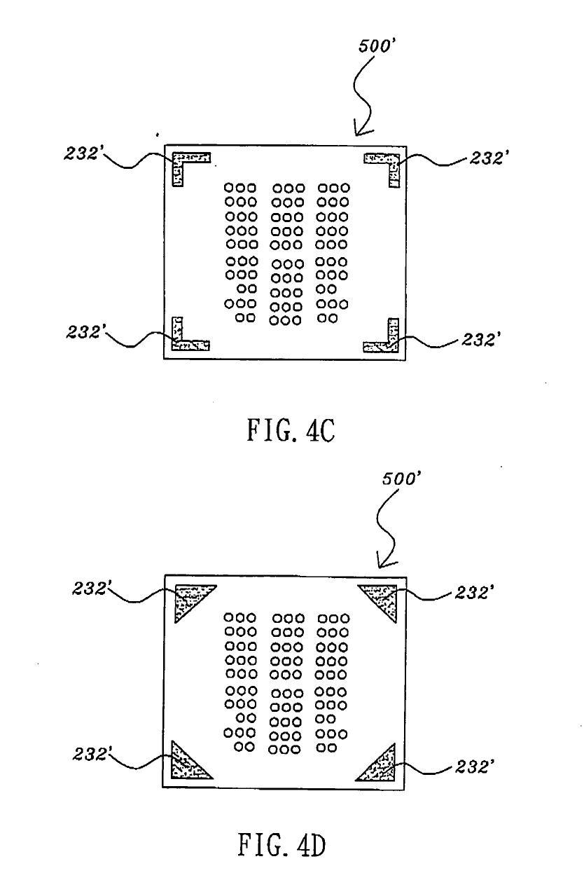

FIG. 4A, FIG. 4B, FIG. 4C and FIG. 4D are illustrations of a bottom view of the structure of BGA package 500′ in accordance with different embodiments of the present invention. According to the location and the shape of the through holes (not shown), the location of the bumps 232′ may be distributed on the BGA package 500′ and relatively around the edge of the die 210′ to provide more forceful supporting. The shape of the through holes (not shown) may be triangle, square, round shape, oval, polygon, bar, multi-radian shape and the shape of the bump 232′ formed by grouting the molding compound into the cavity may be lump (Shown in FIG. 2A), sphere (Shown in FIG. 4A and FIG. 4B), elliptic cylinder prism, polygon prism (Shown in FlG. 4C), triangular prism (Shown in FIG. 4D), bar or polyhedron.

Accordingly, the attachment of the bumps on the symmetrical location of the substrate is utilized in accordance with an embodiment of the present invention. It provides a support when semiconductor package processing the SMT process and avoid the assembly structure disintegration when bear an external force. User may use the semi-conductor module with the assembly structure can avoid damage due to external force (such as user exert too much strength on package itself. As this result the production yield and the lifetime of the assembly structure can be dramatically raise to increase the economic benefits. Furthermore due to the bump of the structure be formed when grouting the molding compound to the cavity, it can be completed during the current assembly process and no extra cost needed and no extra process needed. In the meanwhile, it can raise the production yield and reduce the manufacture cost at the same time.

Although the present invention has been explained in relation to its preferred embodiment, it is to be understood that other modifications and variation can be made without departing the spirit and scope of the invention as hereafter claimed.

What is claimed is:

1. structure of Ball Grid Array (BGA) semi-conductor package comprising:
a substrate with an upper surface and a lower surface, wherein said lower surface has a plurality of electric terminals;
a die attached upon said upper surface of said substrate and electrically connected to said plurality of electric terminals;
a plurality of through holes penetrating through said substrate and located around said die symmetrically;
a molding compound used to cover said die and filled said through holes protruded a plurality of bumps on said lower surface of said substrate; and
a plurality of conductive balls located on said electric terminals individually.

2. The structure of BGA semi-conductor package according to claim 1, wherein said substrate is made of polyimide, glass, aluminum oxide, beryllium oxide or elastomer.

3. The structure of BGA semi-conductor package according to claim 1, wherein said die is electrically connected with said electric terminals via a plurality of wires.

4. The structure of BGA semi-conductor package according to claim 3, wherein said wires are made of aurum material (Au).

5. The structure of BGA semi-conductor package according to claim 1, wherein said molding compound is made of epoxy.

6. The structure of BGA semi-conductor package according to claim 1, wherein said conductive balls are made of metal tin (Sn).

7. The structure of BGA semi-conductor package according to claim 1, wherein the shape of said plurality of through holes is in round shape, oval, polygon, bar or multi-radian shape.

8. The structure of BGA semi-conductor package according to claim 1, wherein the shape of said bumps is in sphere, elliptic cylinder, polygon prism, bar prism or polyhedron shape.

9. Electric apparatus comprising:
a substrate with an upper surface and a lower surface, wherein said lower surface has a plurality of electric terminals;
a die attached on said upper surface of said substrate and electrically connected to said plurality of electric terminals;
a plurality of through holes penetrated through said substrate and located around said die symmetrically;
a molding compound covered said die, filled said through holes and protruded a plurality of bumps on said lower surface of said substrate;
a plurality of conductive balls located on said electric terminals individually; and
a print circuit board with a conductive connection region electrically connected with said plurality of conductive balls.

10. The electric apparatus according to claim 9, wherein said substrate is made of polyimide, glass, aluminum oxide, beryllium oxide or elastomer.

11. The electric apparatus according to claim 9, wherein said molding compound is made of epoxy.

12. The electric apparatus according to claim 9, wherein the height of said plurality of bumps is shorter than the height between said substrate and said print circuit board.

13. The electric apparatus according to claim 9, wherein the shape of said plurality of through holes is in round shape, oval, polygon, bar or multi-radian shape.

14. The electric apparatus according to claim 9, wherein the shape of said bumps is in sphere, elliptic cylinder, polygon prism, bar prism or polyhedron shape.
